(19) United States
(12) Patent Application Publication
(10) Pub. No.: US 2023/0262949 A1
(43) Pub. Date: Aug. 17, 2023

(54) ALIGNING DEVICE AND ALIGNING METHOD

(71) Applicant: SAMSUNG ELECTRONICS CO., LTD., Suwon-si (KR)

(72) Inventors: Kyoshik HAN, Suwon-si (KR); Youngwook Kwon, Suwon-si (KR); Bongho Suk, Suwon-si (KR); Kangho Kim, Suwon-si (KR); Myeonggu Kim, Suwon-si (KR); Seungjong Yu, Suwon-si (KR); Changwoo Yu, Suwon-si (KR); Youngmin Cho, Suwon-si (KR)

(73) Assignee: SAMSUNG ELECTRONICS CO., LTD., Suwon-si (KR)

(21) Appl. No.: 17/942,865

(22) Filed: Sep. 12, 2022

(30) Foreign Application Priority Data
Feb. 11, 2022 (KR) 10-2022-0018413
Mar. 15, 2022 (KR) 10-2022-0031882

(51) Int. Cl. H05K 13/00; B23Q 3/18; H05K 13/04

(52) U.S. Cl. CPC H05K 13/0015; B23Q 3/186; H05K 13/0409; H01L 33/005

(57) ABSTRACT

According to various embodiments of the disclosure, an aligning device may include a body part including a body and a mask plate, wherein the body is configured to receive a movement by a first moving part and includes a body hole and the mask plate is configured to receive a movement by a second moving part and includes a mask plate hole and a head part disposed on the body part and configured to receive a movement by a third moving part. The mask plate may be disposed between the body and the head part and is configured to receive the movement by the second moving part to move between the body and the head part.

### CROSS-REFERENCE TO RELATED APPLICATION(S)

This application is based on and claims priority under 35 U.S.C. § 119 to Korean Patent Application Nos. 10-2022-0018413 and 10-2022-0031882, filed on Feb. 11, 2022 and Mar. 15, 2022, in the Korean Intellectual Property Office, the disclosure of which are herein incorporated by reference in their entireties.

### TECHNICAL FIELD

Various embodiments of the disclosure relate to an aligning device and an aligning method.

### DESCRIPTION OF RELATED ART

An electronic device may be equipped with various electronic components. An example electronic component may be a light emitting diode (LED) that generates light. A light emitting diode may generate light and transfer various pieces of information to the user. One type of light emitting diode may be a micro light emitting diode. Micro light emitting diodes are used in displays and have an advantage in response time and energy efficiency as compared to conventional liquid crystal displays (LCDs) and in efficiency and use time as compared to organic light emitting diodes (OLEDs).

With various aspects as compared with the conventional electronic components, micro light emitting diodes are being actively studied for commercial use as a display. To use micro light emitting diodes in a display, a great number of micro light emitting diodes should be precisely and quickly disposed. However, due to their micro size and use in great numbers, micro light emitting diodes are hard to place in a precise manner. Thus, a need exists for technology for precisely and quickly disposing small-sized electronic components.

### SUMMARY

According to various embodiments of the disclosure, an aligning device may include a body part including a body receiving a movement by a first moving part and having a body hole and a mask plate receiving a movement by a second moving part and having a mask plate hole and a head part disposed on the body part and receiving a movement by a third moving part. The mask plate may be disposed between the body and the head part and receives the movement by the second moving part, to move between the body and the head part.

According to various embodiments of the disclosure, an aligning device may include a body part including a body receiving a movement by a first moving part and having a body hole and a mask plate receiving a movement by a second moving part and having a mask plate hole and a head part disposed on the body part and receiving a movement by a third moving part. The mask plate may be disposed between the body and the head part and receives the movement by the second moving part to move between the body and the head part. The body may be supported by a body support part, and the body support part is supported by a metal support part. A body chamber surrounded by the body, the body support part, and the metal support part may be formed.

According to various embodiments of the disclosure, an aligning method may include a operation of sucking a plurality of raw materials using a head part, a operation of separating the raw material from the head part and disposing the raw material in a mask plate hole formed in a mask plate, a primary alignment operation of aligning the plurality of raw materials by moving the mask plate, and a secondary alignment operation of moving the mask plate to align the plurality of raw materials to have a constant interval therebetween.

According to various embodiments of the disclosure, the aligning device may align all of electronic components in various sizes, particularly micro light emitting diodes in various sizes, through a single process.

### BRIEF DESCRIPTION OF THE DRAWINGS

A more complete appreciation of the disclosure and many of the attendant aspects thereof will be readily obtained as the same becomes better understood by reference to the following detailed description when considered in connection with the accompanying drawings, wherein:

FIG. 1 is a perspective view illustrating an aligning device according to various embodiments of the disclosure;

FIG. 2 is a perspective view illustrating a body part and a moving part according to various embodiments of the disclosure;

FIG. 3 is a front view illustrating a body part, a moving part, and a head part according to various embodiments of the disclosure;

FIG. 4 is a front view illustrating a body, a mask plate, and a head part according to various embodiments of the disclosure;

FIG. 5 is a bottom view illustrating a head part according to various embodiments of the disclosure;

FIG. 6 is a cross-sectional view illustrating a head part and a raw material part, taken along X-Z plane according to various embodiments of the disclosure;

FIG. 7 is a cross-sectional view illustrating a body part, a head part, and a raw material part, taken along X-Z plane according to various embodiments of the disclosure;

FIG. 8 is a cross-sectional view illustrating a body part where a raw material is disposed, taken along X-Z plane according to various embodiments of the disclosure;

FIG. 9 is a cross-sectional view illustrating a body part and a raw material part, taken along X-Z plane according to various embodiments of the disclosure;

FIG. 10 is a plan view illustrating a mask plate disposed on a body according to various embodiments of the disclosure;

FIG. 11 is a plan view illustrating a mask plate and a raw material disposed on a body according to various embodiments of the disclosure;

FIGS. 12, 13, 14, 15, and 16 are plan views illustrating a body part and a raw material according to various embodiments of the disclosure; and

FIG. 17 is a flowchart illustrating a method for aligning a raw material according to various embodiments of the disclosure.

### DETAILED DESCRIPTION

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., program) including one or more instructions that are stored in a storage medium (e.g., internal memory or external memory) that is readable by a machine (e.g., the electronic device). For example, a processor (e.g., the processor) of the machine (e.g., the electronic device) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

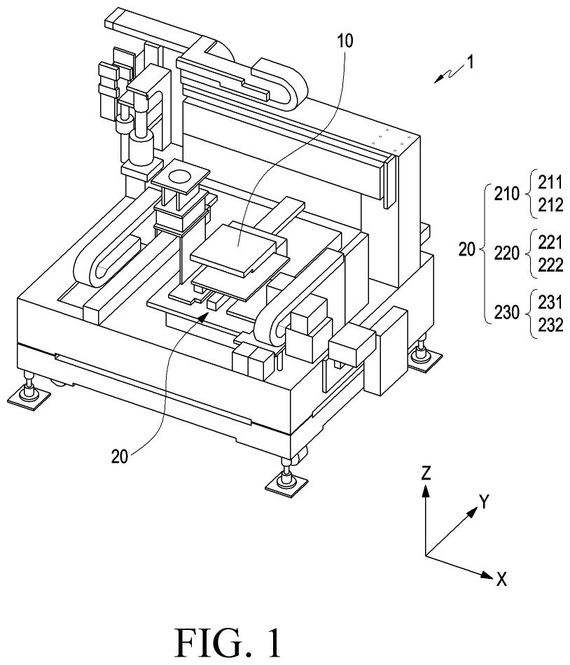

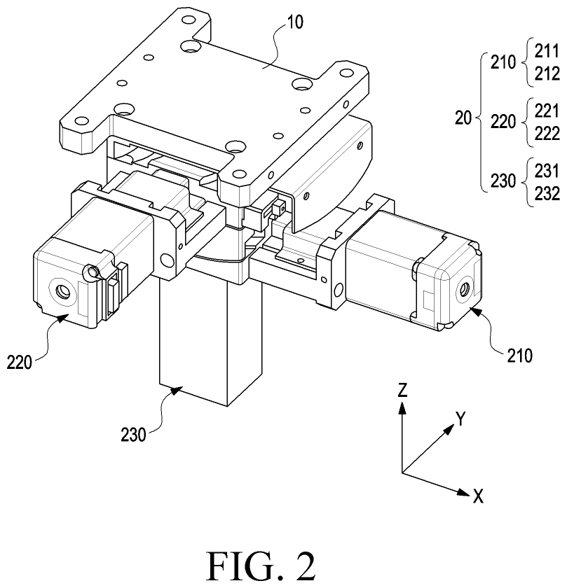

FIG. 1 is a perspective view illustrating an aligning device according to various embodiments of the disclosure. FIG. 2 is a perspective view illustrating a body part and a moving part according to various embodiments of the disclosure.

Referring to FIGS. 1 and 2, according to various embodiments, an aligning device 1 may include a body part 10 and a moving part 20. According to an embodiment, the body part 10 may be connected to the moving part 20 to receive a movement and rotational movement from the moving part 20. According to an embodiment, the moving part 20 may include an X-axis moving part 210, a Y-axis moving part 220, and a Z-axis moving part 230.

According to various embodiments, the X-axis moving part 210 may include an X-axis horizontal moving part 211 and an X-axis rotating part 212. The X-axis horizontal moving part 211 may provide the body part 10 with horizontal movement in the X-axis direction. For example, the X-axis horizontal moving part 211 may provide the body part 10 with horizontal movement in the +X-axis or −X-axis direction. The X-axis rotating part 212 may provide the body unit 10 with rotational movement about one axis parallel to the X-axis. For example, the X-axis rotating part 212 may provide the body part 10 with a clockwise rotational or counterclockwise rotational movement about an axis parallel to the X-axis.

According to various embodiments, the Y-axis moving part 220 may include a Y-axis horizontal moving part 221 and a Y-axis rotating part 222. The Y-axis horizontal moving part 221 may provide the body 10 with horizontal movement in the Y-axis direction. For example, the Y-axis horizontal moving part 221 may provide the body part 10 with horizontal movement in the +Y-axis or −Y-axis direction. The Y-axis rotating part 222 may provide the body unit 10 with rotational movement about one axis parallel to the Y-axis. For example, the Y-axis rotating part 222 may provide the body part 10 with a clockwise rotational or counterclockwise rotational movement about an axis parallel to the Y-axis.

According to various embodiments, the Z-axis moving part 230 may include a Z-axis horizontal moving part 231 and a Z-axis rotating part 232. The Z-axis horizontal moving part 231 may provide the body 10 with horizontal movement in the Z-axis direction. For example, the Z-axis horizontal moving part 231 may provide the body part 10 with horizontal movement in the +Z-axis or −Z-axis direction. The Z-axis rotating part 232 may provide the body unit 10 with rotational movement about one axis parallel to the Z-axis. For example, the Z-axis rotating part 232 may provide the body part 10 with a clockwise rotational or counterclockwise rotational movement about an axis parallel to the Z-axis.

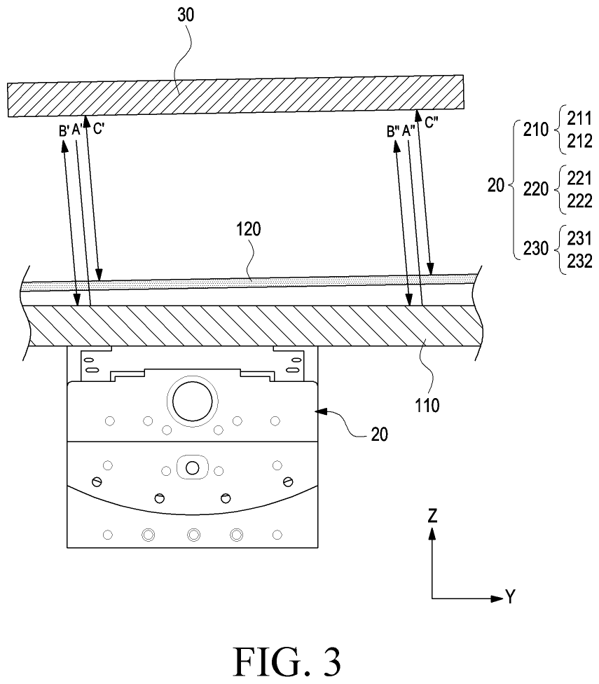

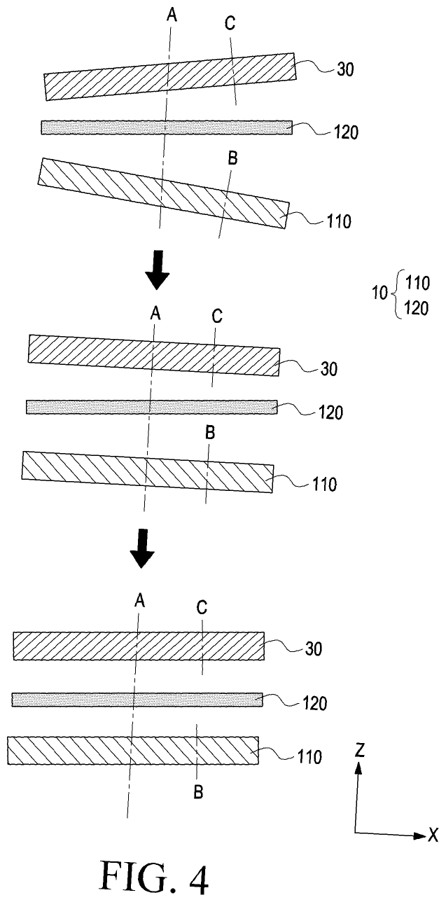

FIG. 3 is a front view illustrating a body part, a moving part, and a head part according to various embodiments of the disclosure. FIG. 4 is a front view illustrating a body, a mask plate, and a head part according to various embodiments of the disclosure.

The body part 10 and the moving part 20 shown in FIGS. 3 and 4 may be the same as or similar to the body part 10 and the moving part 20 shown in FIGS. 1 and 2. Accordingly, no description is given of the same components.

Referring to FIGS. 3 and 4, according to various embodiments, the aligning device (e.g., the aligning device 1 of FIG. 1) may further include a head part 30. According to various embodiments, the body part 10 may include a body 110 and a mask plate 120.

According to various embodiments, the body 110, the mask plate 120, and the head part 30 are movable in the X-axis, Y-axis, and Z-axis directions. Further, the body 110, the mask plate 120, and the head part 30 may be rotated around an axis parallel to the X axis, another axis parallel to the Y axis, and still another axis parallel to the Z axis.

Referring to FIG. 3, according to various embodiments, normal directions A′ and A″ extending from one surface of the body 110 and normal to the mask plate 120, normal directions B′ and B″ normal to one surface of the mask plate 120, and normal directions C′ and C″ extending to and from one surface of the head part 30 may be parallel to each other.

Referring to FIG. 4, according to various embodiments, the head part 30, the body 110, and the mask plate 120 may move independently of each other. Since the body 110, the mask plate 120, and the head part 30 may move independently of each other, the normal A to one surface of the body 110, the normal B to one surface of the mask plate 120, and the normal C to one surface of the head part 30 may not be parallel to each other.

According to various embodiments, the head part 30, the body 110, and the mask plate 120 may receive movement by the moving part 20. The head part 30, the body 110, and the mask plate 120 may move independently of each other. Movements of the head part 30, the body 110, and the mask plate 120 include horizontal movement, vertical movement, and rotation.

According to various embodiments, through the rotation of each of the body 110, the mask plate 120, and the head part 30, the normal A to one surface of the body 110, the normal B to one surface of the mask plate 120, and the normal C to one surface of the head part 30 may be adjusted to be parallel to each other. For example, the parallelism of the head part 30, the parallelism of the body 110, and/or the parallelism of the mask plate 120 may be adjusted so that the normals A, B, and C are parallel to each other.

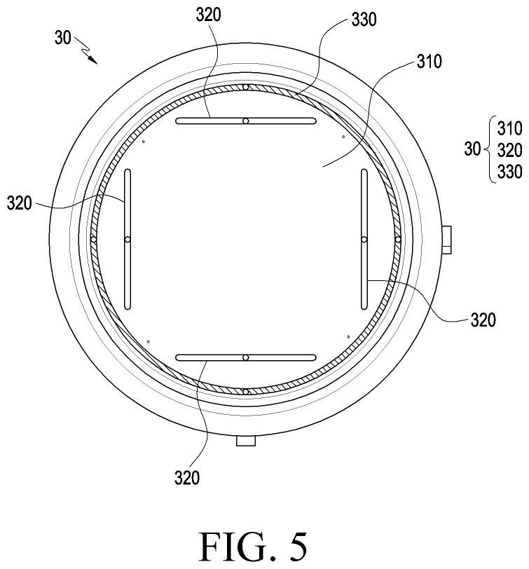

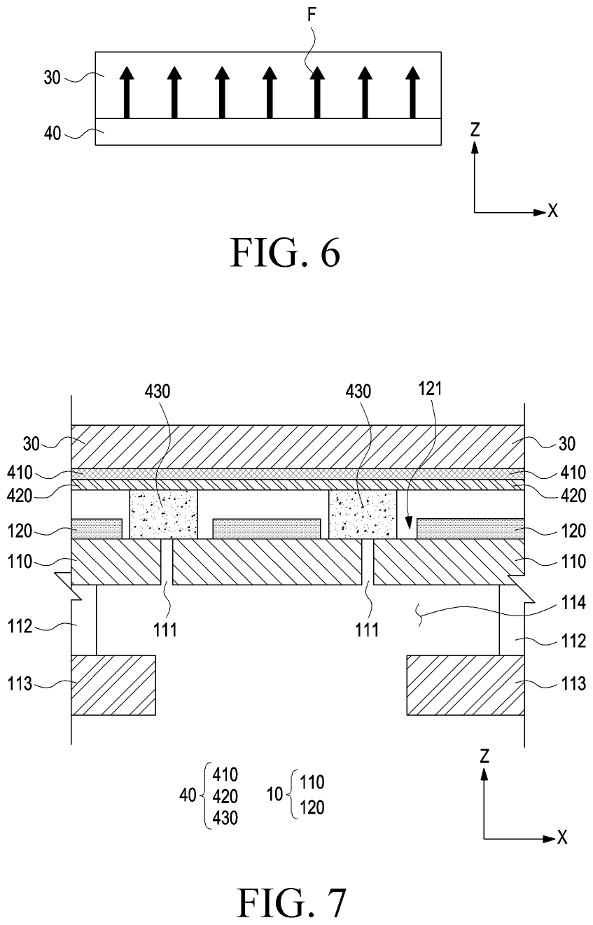

FIG. 5 is a bottom view illustrating a head part according to various embodiments of the disclosure. FIG. 6 is a cross-sectional view illustrating a head part and a raw material part, taken along X-Z plane according to various embodiments of the disclosure.

The head part 30 illustrated in FIGS. 5 and 6 may be the same as or similar to the head part 30 illustrated in FIGS. 1, 2, 3, and 4. Accordingly, no description is given of the same components.

Referring to FIG. 5, according to various embodiments, the head part 30 may have a circular shape. The head part 30 may include a suction surface 310, a suction line 320, and a suction curve 330.

According to various embodiments, the suction surface 310 may be formed flat to contact a raw material part 40. The suction line 320 and the suction curve 330 may be formed on at least a portion of the suction surface 310. The suction line 320 may be a long groove and be connected to a device for generating negative pressure. The suction lines 320 may be formed symmetrically to each other. The shape in which the plurality of suction lines 320 are formed may be a rectangle. The suction curve 330 may be formed farther from the center of the head part 30 than the suction line 320 is. The shape of the suction curve 330 may be a circular recess and be connected to a device for generating negative pressure.

Referring to FIG. 6, according to various embodiments, the raw material part 40 may be disposed on the bottom surface of the head part 30. The raw material part 40 may be disposed to contact the suction surface 310 of the head part 30. The raw material part 40 may be disposed to be in tight contact with or may be urged toward the suction surface 310 by the negative pressure generated at the suction line 320 and/or the suction curve 330. The strength F of the negative pressure (vacuum pressure) generated at the suction line 320 and/or the suction curve 330 may be about 50 kilopascals (KPa) or more. As a negative pressure (vacuum pressure) of about 50 kilopascals or more is generated, the raw material part 40 may be sucked so as to be disposed parallel to the suction surface 310 of the head part 30.

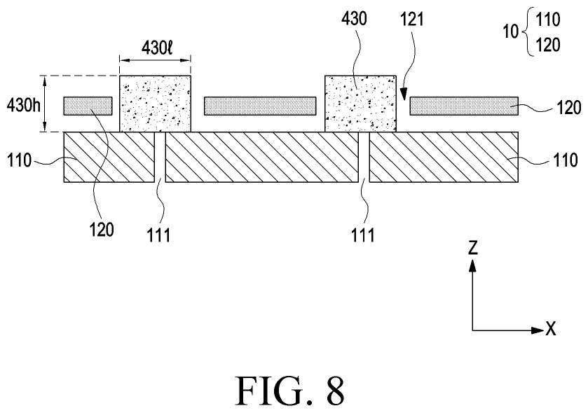

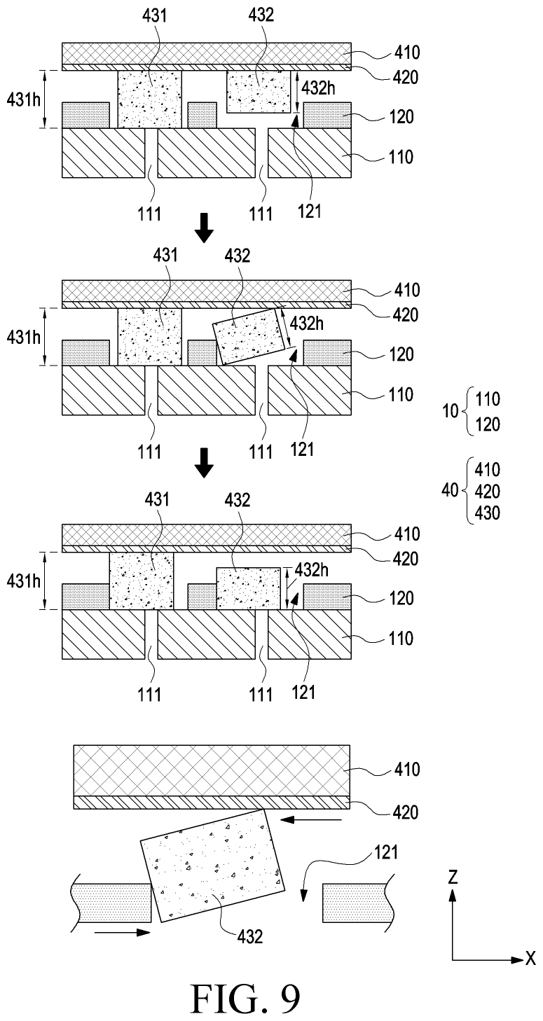

FIG. 7 is a cross-sectional view illustrating a body part, a head part, and a raw material part, taken along X-Z plane according to various embodiments of the disclosure. FIG. 8 is a cross-sectional view illustrating a body part where a raw material is disposed, taken along X-Z plane according to various embodiments of the disclosure. FIG. 9 is a cross-sectional view illustrating a body part and a raw material part, taken along X-Z plane according to various embodiments of the disclosure.

The body part 10 including the body 110 and the mask plate 120, the head part 30, and the raw material part 40 disclosed in FIGS. 7, 8, and 9 may be the same as or similar to the body part 10, the body 110, the mask plate 120, the head part 30, and the raw material part 40 disclosed in FIGS. 1, 2, 3, 4, 5, and 6. Accordingly, no description is given of the same components.

Referring to FIG. 7, according to various embodiments, the raw material part 40 may be disposed to be sucked to the head part 30. The raw material part 40 may include a raw material film 410, an adhesive 420, and a raw material 430.

According to various embodiments, the shape of the raw material film 410 may be a thin plate. The adhesive 420 may be applied to one surface of the raw material film 410. The raw material 430 may be disposed to be adhered to the raw material film 410 by the adhesive 420.

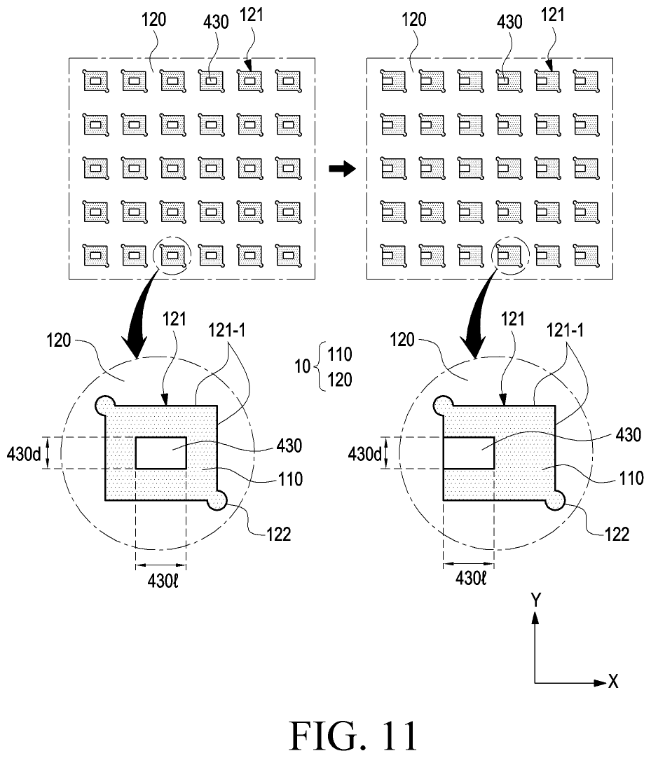

According to various embodiments, the raw material 430 may be a micro light emitting diode 430. The size of the raw material 430 may be very small. For example, the length (e.g., 430l of FIG. 8) of the raw material 430 may be about 150 μm or less. The height (e.g., 430h of FIG. 8) of the raw material 430 may be about 50 μm to about 70 μm. The width (e.g., 430d of FIG. 11) of the raw material 430 may be about 150 μm or less. The distance between one raw material 430 disposed on the raw material film 410 and another adjacent raw material 430 may be about 500 μm to about 1000 μm.

According to various embodiments, a plurality of mask plate holes 121 may be formed in the mask plate 120. The arrangement of the mask plate holes 121 may correspond to the raw materials (micro light emitting diodes) 430 disposed on the raw material film 410.

According to various embodiments, the body 110 may be disposed under the mask plate 120 (−Z-axis direction). For example, the mask plate 120 may be disposed between the head part 30 and the body 110. Further, the raw material part 40 may be disposed between the mask plate 120 and the head part 30.

According to various embodiments, a plurality of body holes 111 may be formed in the body 110. The positions of the plurality of body holes 111 may correspond to the positions of the plurality of mask plate holes 121. The body hole 111 may be connected to the body chamber 114.

According to various embodiments, a body support part 112 may be disposed under the body 110 (in the −Z-axis direction). A metal support part 113 may be disposed under the body support part 112 (in the −Z-axis direction). The body support part 112 and/or the metal support part 113 may be disposed under the body 110 (in the −Z-axis direction) to prevent the body 110 from being deformed in one direction (e.g., −Z-axis direction).

According to various embodiments, the body chamber 114 may refer to a space surrounded by the body 110, the body support part 112, and/or the metal support part 113. The body chamber 114 may be connected to a device for generating a vacuum pressure, so that the pressure therein may be lower than atmospheric pressure. The body chamber 114 with lower than atmospheric pressure may be connected to the plurality of body holes 111, so that a vacuum pressure may be generated in a position adjacent to the plurality of body holes 111. As vacuum pressure is generated in the position adjacent to the body hole 111, the raw material 430 may be separated from the raw material film 410. Further, the raw material 430 may be sucked to the body hole 111, and may be disposed on the body 110.

Referring to FIG. 8, according to various embodiments, the mask plate 120 may move in one direction (+Z-axis direction). According to an embodiment, the mask plate 120 may move in one direction (+Z-axis direction) by about half of the height 430h of the raw material 430. As the mask plate 120 is spaced apart from the body 110, friction with the body 110 may not occur when the mask plate 120 moves. Further, as the mask plate 120 moves while being spaced apart from the body 110, when the raw material 430 is separated from the raw material film 410, the raw material 430 may be prevented from being separated from the body 110.

Referring to FIG. 9, according to various embodiments, the sizes of the plurality of raw materials 430 may be different from each other. For example, the height 431h of the first raw material 431 may be larger than the height 432h of the second raw material 432. If the sizes of the plurality of raw materials 430 are different from each other, all of the plurality of raw materials 430 may not be separated from the raw material film 410 due to the adhesive 420. To separate the plurality of raw materials 430 from the raw material film 410, the mask plate 120 may move in one direction (X-axis or Y-axis). As the mask plate 120 moves in one direction (X-axis or Y-axis), the second raw material 432 having a small height 432h may come into contact with the mask plate 120 and receive an external force. Torque may be generated in the second raw material 432 due to an external force from the mask plate 120 and an adhesive force with the adhesive 420. As a clockwise or counterclockwise torque is generated in the second raw material 432, at least a portion of the second raw material 432 may be separated from the adhesive 420. At least a portion of the second raw material 432 that is at least partially separated from the adhesive 420 may be closer to the body hole 111. As the distance between the second raw material 432 and the body hole 111 decreases, the second raw material 432 may be completely separated from the adhesive 420 by the vacuum pressure generated in the position adjacent to the body hole 111. As described above, as the mask plate 120 moves in one direction (X-axis or Y-axis), all of the plurality of raw materials 430 in various sizes may be separated from the raw material film 410.

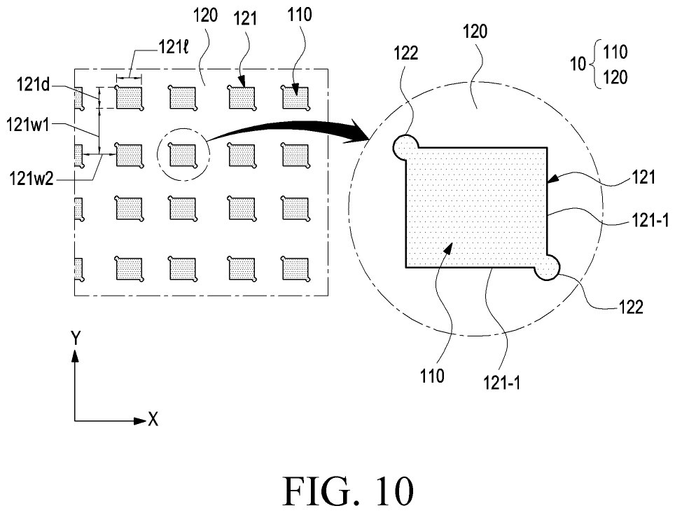

FIG. 10 is a plan view illustrating a mask plate disposed on a body according to various embodiments of the disclosure. FIG. 11 is a plan view illustrating a mask plate and a raw material disposed on a body according to various embodiments of the disclosure.

The body part 10, the body 110, the mask plate 120, the mask plate hole 121, and the raw material 430 disclosed in FIGS. 10 and 11 may be the same as or similar to the body part 10, the body 110, the mask plate 120, the mask plate hole 121, and the raw material 430 disclosed in are shown in FIGS. 1, 2, 3, 4, and 11. 5, 6, 7, 8, and 9. Accordingly, no description is given of the same components.

Referring to FIG. 10, the body part 10 may include a body 110 and a mask plate 120. At least a portion of the body 110 may be exposed through the mask plate hole 121 formed in the mask plate 120.

According to various embodiments, the length 121l of the mask plate hole 121 may be about 250 μm to about 300 μm. The width 121d of the mask plate hole 121 may be about 250 μm to about 300 μm. A vertical distance 121w1 between one mask plate hole 121 and another adjacent mask plate hole 121 may be about 600 μm to about 900 μm. A horizontal distance 121w2 between one mask plate hole 121 and another adjacent mask plate hole 121 may be about 600 μm to about 900 μm.

According to various embodiments, a mask plate hole boundary 121-1 may be formed along the periphery of the mask plate hole 121. In one mask plate hole 121, a recess hole 122 may be formed between one mask plate hole boundary 121-1 and another mask plate hole boundary 121-1. The shape of the recess hole 122 may be somewhat circular. The recess hole 122 may be formed in a position corresponding to the vertex of the mask plate hole 121 formed in a square shape. The recess holes 122 may be formed in positions corresponding to the opposite vertices of the mask plate hole 121 formed in a square shape. According to an embodiment, the recess holes 122 may be formed in positions corresponding to all vertices of the mask plate hole 121 formed in a square shape. As the recess hole 122 is formed, the raw material 430 may be disposed parallel to the mask plate hole boundary 121-1.

Referring to FIG. 11, according to various embodiments, the mask plate 120 may move in one direction (X-axis or Y-axis) to separate the raw material 430 from the raw material film 410.

According to various embodiments, when the raw material 430 has a rectangular shape in which the length 430l and the width 430d are different from each other, e.g., when the length 430l is larger than the width 430d, the mask plate 120 may move in the X-axis direction parallel to the length 430l of the raw material 430 (example of FIG. 11). As another example, when the length 430l is smaller than the width 430d, the mask plate 120 may move in the Y-axis direction parallel to the width 430d of the raw material 430. As the raw material 430 is separated from the raw material film 410 by moving the mask plate 120 parallel to the larger of the length 430l and the width 430d of the raw material 430, the raw material A may be prevented from being turned over and separated from the film 410.

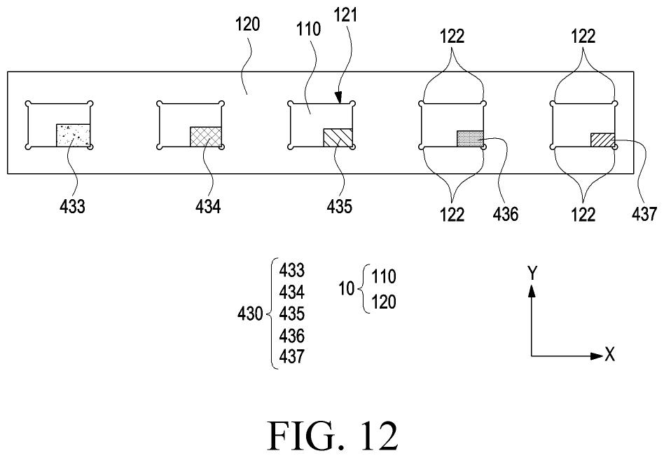

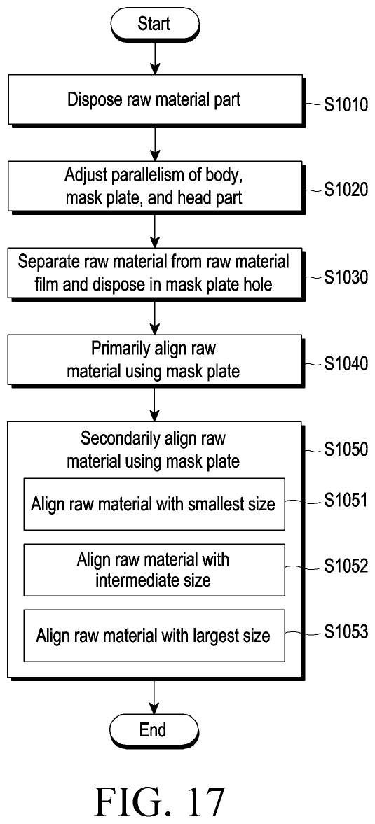

FIGS. 12, 13, 14, 15, and 16 are plan views illustrating a body part and a raw material according to various embodiments of the disclosure. FIG. 17 is a flowchart illustrating a method for aligning a raw material according to various embodiments of the disclosure.

The body part 10, the body 110, the mask plate 120, the mask plate hole 121, the recess hole 122, and the raw material 430 disclosed in FIGS. 12, 13, 14, 15, and 16 may be the same as or similar to the body part 10, body 110, the mask plate 120, the mask plate hole 121, the recess hole 122, and the raw material 430 disclosed in FIGS. 1, 2, 3, 4, 5, 6, 7, 8, 9, 10, and 11. Accordingly, no description is given of the same components.

Hereinafter, he description of the flowchart shown in FIG. 17 is given along with the description of FIGS. 12, 13, 14, 15, and 16.

According to various embodiments, the raw material part 40 may be disposed to be sucked to the head part (e.g., the head part 30 of FIG. 7) (operation S1010 of FIG. 17). The raw material part 40 sucked to the head part 30 may be disposed on the upper portion (+Z-axis direction) of the mask plate 120 through movement of the head part 30.

According to various embodiments, the parallelism of the head part 30, the body 110, and the mask plate 120 may be adjusted, so that the head part 30, the body 110, and the mask plate 120 are parallel to each other (operation S1020 of FIG. 17).

According to various embodiments, through movement of the mask plate 120 (movement in the X-axis, Y-axis, and/or Z-axis), the raw material 430 may be separated from the raw material film 410, and the raw material 430 may be disposed in the mask plate hole 121 (operation S1030 of FIG. 17).

According to various embodiments, the mask plate 120 may be moved (movement in the X-axis and/or Y-axis) so that all the raw materials 430 come into contact with at least two adjacent mask plate hole boundaries 121-1 of the plurality of mask plate holes 121 (operation S1040 of FIG. 17). As the mask plate 120 is moved so that all the raw materials 430 come in contact with the at least two adjacent mask plate hole boundaries 121-1 of the plurality of mask plate holes 121, the raw materials 430 may be primarily aligned. The primarily aligned state may be identified with reference to FIG. 12.

Referring to FIG. 12, raw materials 430 in various sizes are disposed. A third raw material 433 having the largest size is disposed at one end in the −X-axis direction. The raw materials 430 are disposed which reduce in size in the +X axis, and a seventh raw material 437 having the smallest size is disposed at the other end in the +X direction.

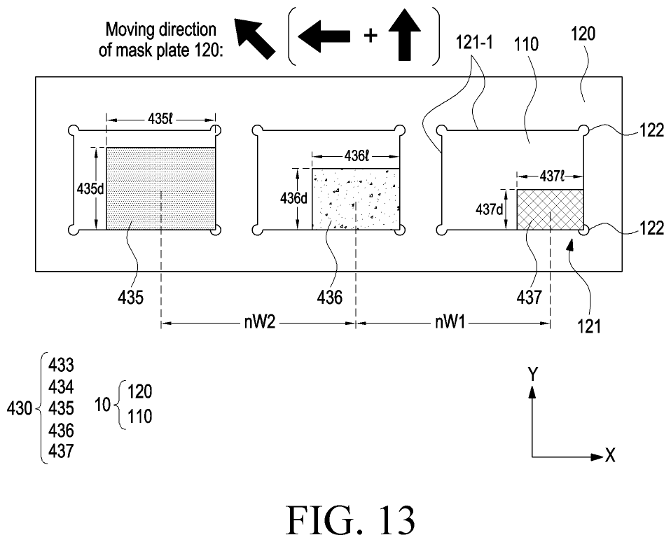

FIGS. 13, 14, 15, and 16 sequentially illustrate that the primarily aligned raw materials 430 having different sizes, e.g., the fifth raw material 435 having the largest size, the sixth raw material 436 having an intermediate size, and the seventh raw material 437 having the smallest size are secondarily aligned (operation S1050 of FIG. 17).

Referring to FIG. 13, the fifth raw material 435, the sixth raw material 436, and the seventh raw material 437, primarily aligned, may be identified. To primarily align the raw materials 430, the mask plate 120 may be moved in the −X-axis direction and the +Y-axis direction (operation S1040 of FIG. 17). The moving directions of the mask plate 120 are not limited to the −X-axis direction and the +Y-axis direction.

According to various embodiments, it may be identified that the length 435l of the fifth raw material 435 is larger than the width 435d, the length 436l of the sixth raw material 436 is larger than the width 436d, and the length 437l of the seventh raw material 437 is larger than the width 436d. Further, it may be identified that the distance nW2 between the center of the fifth raw material 435 and the center of the sixth raw material 436 differs from the distance nW1 between the center of the sixth raw material 436 and the center of the seventh raw material 437.

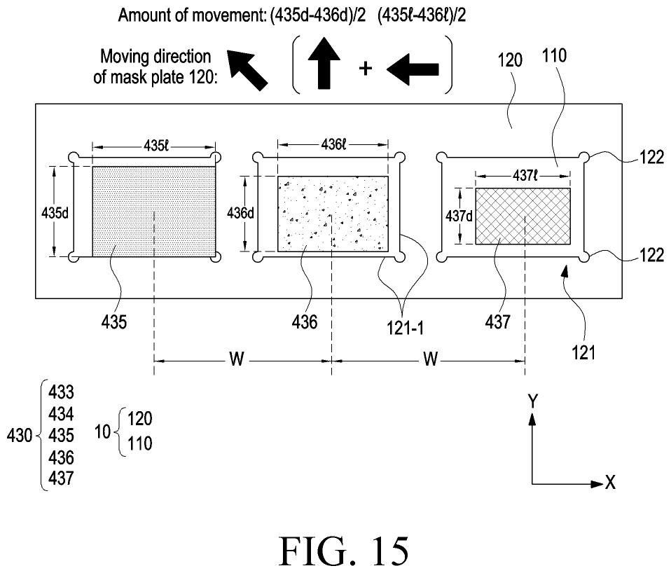

According to various embodiments, the secondary alignment (operation S1050) of FIG. 17 means a process of making the distance (nW2 and/or nW1) between the centers of the raw materials a constant distance (W in FIG. 15).

Referring to FIG. 13, it may be identified that the seventh raw material 437 having the smallest size is aligned (operation S1051 in FIG. 17).

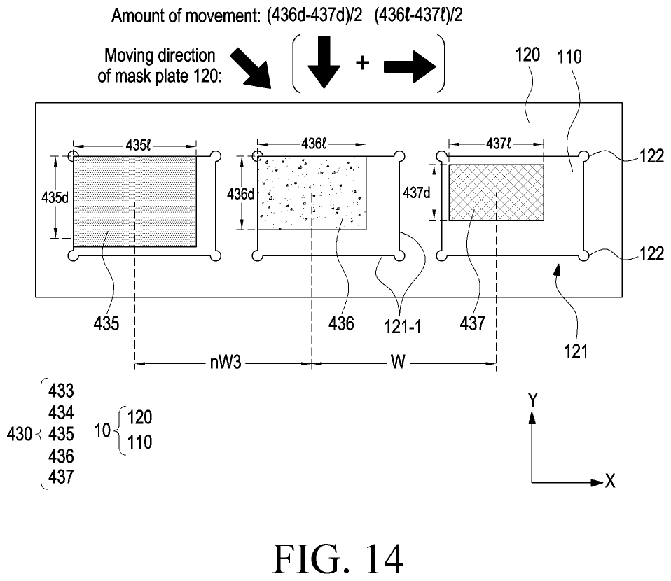

Referring to FIG. 14, it is possible to align the sixth raw material 436 having the intermediate size without moving the aligned seventh raw material 437 by moving the mask plate 120 in the −Y-axis direction and the +X-axis direction (operation S1052 in FIG. 17). The amount of movement of the mask plate 120 in the −Y-axis direction may be half the difference between the sixth raw material width 436d and the seventh raw material width 437d, i.e., [{sixth raw material width 436d−seventh raw material width 437d)}/2]. The amount of movement of the mask plate 120 in the +X-axis direction may be half the difference between the sixth raw material length 436l and the seventh raw material length 437l, i.e., [{sixth raw material length 436l−seventh raw material length 437l}/2]. It may be identified that if the mask plate 120 is so moved, only the fifth raw material 435 and the sixth raw material 436 are moved while the seventh raw material 437 remains stationary. Further, it may be identified that the distance between the center of the sixth raw material 436 and the center of the seventh raw material 437 is changed from the existing distance nW1 to the target distance W. At the same time, it may be identified that the distance between the center of the fifth raw material 435 and the center of the sixth raw material 436 is changed from the existing distance nW2 to a new distance nW3.

Referring to FIG. 15, it is possible to align the fifth raw material 435 having the largest size without moving the aligned sixth raw material 436 and seventh raw material 437 by moving the mask plate 120 in the +Y-axis direction and the −X-axis direction (operation S1053 in FIG. 17). The amount of movement of the mask plate 120 in the +Y-axis direction may be half the difference between the fifth raw material width 435d and the sixth raw material width 436d, i.e., [{fifth raw material width 435d−sixth raw material width 436d}/2]. The amount of movement of the mask plate 120 in the −X-axis direction may be half the difference between the fifth raw material length 435l and the sixth raw material length 436l, i.e., [{fifth raw material length 435l−sixth raw material length 436l)}/2]. It may be identified that if the mask plate 120 is so moved, only the fifth raw material 435 is moved while the sixth raw material 436 and the seventh raw material 437 remain stationary. Further, it may be identified that the distance between the center of the fifth raw material 435 and the center of the sixth raw material 436 is changed from the existing distance nW3 to the target distance W. At the same time, it may be identified that the distance W between the center of the sixth raw material 436 and the center of the seventh raw material 437 is maintained.

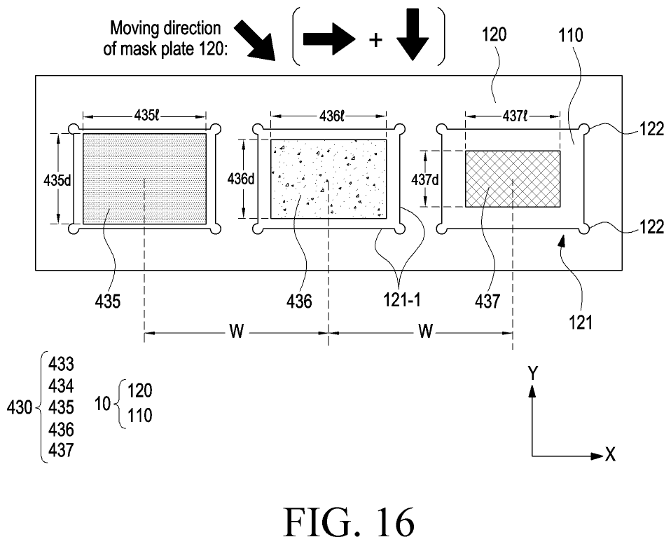

Referring to FIG. 16, all of the raw materials 430 and the mask plate hole boundary 121-1 may be spaced apart by appropriately moving the mask plate 120 in the −Y-axis direction and the +X-axis direction. As such, as all the raw materials 430 and the mask plate hole boundary 121-1 are spaced apart, the raw materials 430 may be easily separated from the body part 10.

According to various embodiments of the disclosure, an aligning device (e.g., the aligning device 1 of FIG. 1) may comprise a body part (e.g., the body part 10 of FIG. 7) including a body (e.g., the body 110 of FIG. 7) receiving a movement by a first moving part and having a body hole (e.g., the body hole 111 of FIG. 7) and a mask plate (e.g., the mask plate 120 of FIG. 7) receiving a movement by a second moving part and having a mask plate hole (e.g., the mask plate hole 121 of FIG. 7), and a head part (e.g., the head part 30 of FIG. 7) disposed on the body part and receiving a movement by a third moving part. The mask plate may be disposed between the body and the head part and receives the movement by the second moving part to move between the body and the head part.

According to various embodiments, the first moving part, the second moving part, and the third moving part may be configured to move independently from each other.

According to various embodiments, the first moving part, the second moving part, and the third moving part may be configured to rotate independently from each other.

According to various embodiments, a vacuum pressure of 50 kilopascals (KPa) or more may be configured to be formed in the body hole.

According to various embodiments, the mask plate hole may be formed in a rectangular shape.

According to various embodiments, at least one recess hole (e.g., the recess hole 122 of FIG. 10) may be formed in a position corresponding to a vertex of the mask plate hole.

According to various embodiments, the head part may include a suction surface (e.g., the suction surface 310 of FIG. 5), a suction line (e.g., the suction line 320 of FIG. 5), and a suction curve (e.g., the suction curve 330 of FIG. 5) and be configured to form a vacuum pressure at the suction line and the suction curve.

According to various embodiments, the aligning device may further comprise a raw material part (e.g., the raw material part 40 of FIG. 7) sucked to the head part.

According to various embodiments, the raw material part may include a raw material film (e.g., the raw material film 410 of FIG. 7), an adhesive (e.g., the adhesive 420 of FIG. 7) applied to a surface of the raw material film, and a raw material (e.g., the raw material 430 of FIG. 7) attached to the raw material film by the adhesive.

According to various embodiments, the raw material may have a size of 1 mm or less and include raw materials having various sizes.

According to various embodiments, by a vacuum pressure formed in the body hole, the raw material may be separated from the raw material film, and the raw material may be disposed in the mask plate hole.

According to various embodiments, the raw material may receive a movement in contact with a mask plate hole boundary (e.g., the mask plate hole boundary 121-1 of FIG. 10) of the mask plate.

According to various embodiments of the disclosure, an aligning device (e.g., the aligning device 1 of FIG. 1) may comprise a body part (e.g., the body part 10 of FIG. 7) including a body (e.g., the body 110 of FIG. 7) receiving a movement by a first moving part and having a body hole (e.g., the body hole 111 of FIG. 7) and a mask plate (e.g., the mask plate 120 of FIG. 7) receiving a movement by a second moving part and having a mask plate hole (e.g., the mask plate hole 121 of FIG. 7), and a head part (e.g., the head part 30 of FIG. 7) disposed on the body part and receiving a movement by a third moving part. The mask plate may be disposed between the body and the head part and receive the movement by the second moving part to move between the body and the head part. The body may be supported by a body support part (e.g., the body support part 112 of FIG. 7), and the body support part may be supported by a metal support part (e.g., the metal support part 113 of FIG. 7). A body chamber (e.g., the body chamber 114 of FIG. 7) surrounded by the body, the body support part, and the metal support part may be formed.

According to various embodiments, the first moving part, the second moving part, and the third moving part may be configured to move independently from each other.

According to various embodiments, the first moving part, the second moving part, and the third moving part may be configured to rotate independently from each other.

According to various embodiments, a vacuum pressure of 50 kilopascals (KPa) or more may be configured to be formed in the body hole.

According to various embodiments, the mask plate hole may be formed in a rectangular shape.

According to various embodiments of the disclosure, an aligning method may comprise a operation (S1010 of FIG. 17) of sucking a plurality of raw materials (e.g., the raw material 430 of FIG. 7) using a head part (e.g., the head part 30 of FIG. 7), a operation (e.g., S1030 of FIG. 17) of separating the raw material from the head part and disposing the raw material in a mask plate hole (e.g., the mask plate hole 121 of FIG. 7) formed in a mask plate (e.g., the mask plate 120 of FIG. 7), a primary alignment operation (S1040 of FIG. 17) of aligning the plurality of raw materials by moving the mask plate, and a secondary alignment operation (S1050 of FIG. 17) of moving the mask plate to align the plurality of raw materials to have a constant interval therebetween.

According to various embodiments, the operation of separating the raw material from the head part may suck the raw material using a vacuum pressure generated in a body hole formed in a body (e.g., the body 110 of FIG. 7).

According to various embodiments, the secondary alignment operation may include a operation (S1051, S1052, and S1053 of FIG. 17) of aligning the plurality of raw materials from a raw material with a small size.

While the disclosure has been shown and described with reference to exemplary embodiments thereof, it will be apparent to those of ordinary skill in the art that various changes in form and detail may be made thereto without departing from the spirit and scope of the disclosure as defined by the following claims.

What is claimed is:

1. An aligning device comprising:
a body part comprising a body and a mask plate, the body being configured to receive a movement by a first moving part and the body comprising a body hole, and the mask plate being configured to receive a movement by a second moving part and the mask plate comprising a mask plate hole; and
a head part disposed on the body part and configured to receive a movement by a third moving part,
wherein the mask plate is disposed between the body and the head part and is configured to receive the movement by the second moving part, to move between the body and the head part.

2. The aligning device of claim 1, wherein the first moving part, the second moving part, and the third moving part are configured to move independently.

3. The aligning device of claim 1, wherein the first moving part, the second moving part, and the third moving part are configured to rotate independently.

4. The aligning device of claim 1, wherein the body hole has a vacuum pressure of 50 kilopascals (KPa) or more. shape.

5. The aligning device of claim 1, wherein the mask plate hole is formed in a rectangular shape.

6. The aligning device of claim 5, wherein at least one recess hole is formed in a position corresponding to a vertex of the mask plate hole.

7. The aligning device of claim 1, wherein the head part comprises a suction surface, a suction line, and a suction curve and the head part is configured to form a vacuum pressure at the suction line and the suction curve.

8. The aligning device of claim 1, further comprising a raw material part that is sucked to the head part.

9. The aligning device of claim 8, wherein the raw material part comprises a raw material film, an adhesive applied to a surface of the raw material film, and a raw material attached to the raw material film by the adhesive.

10. The aligning device of claim 9, wherein the raw material has a size of 1 mm or less and includes raw materials having various sizes.

11. The aligning device of claim 9, wherein by a vacuum pressure formed in the body hole, the raw material is separated from the raw material film, and the raw material is disposed in the mask plate hole.

12. The aligning device of claim 11, wherein the raw material is configured to receive a movement in contact with a mask plate hole boundary of the mask plate.

13. An aligning device comprising:
a body part comprising a body and a mask plate, the body being configured to receive a movement by a first moving part and the body comprising a body hole and the mask plate being configured to receive a movement by a second moving part and the mask plate comprising a mask plate hole; and
a head part disposed on the body part and configured to receive a movement by a third moving part,
wherein the mask plate is disposed between the body and the head part and the mask palte is configured to receive the movement by the second moving part, to move between the body and the head part,
wherein the body is supported by a body support part, and the body support part is supported by a metal support part, and
wherein the aligning device comprises a body chamber surrounded by the body, the body support part, and the metal support part.

14. The aligning device of claim 13, wherein the first moving part, the second moving part, and the third moving part are configured to move independently.

15. The aligning device of claim 13, wherein the first moving part, the second moving part, and the third moving part are configured to rotate independently.

16. The aligning device of claim 13, wherein the body hole has a vacuum pressure of 50 kilopascals (KPa) or more.

17. The aligning device of claim 13, wherein the mask plate hole is formed in a rectangular shape.

18. An aligning method comprising:
sucking a plurality of raw materials using a head part;
separating the raw material from the head part and disposing the raw material in a mask plate hole formed in a mask plate;
aligning the plurality of raw materials by moving the mask plate; and
moving the mask plate to align the plurality of raw materials so that the plurality of raw materials have a constant interval therebetween.

19. The aligning method of claim 18, wherein separating the raw material from the head part comprises sucking the raw material using a vacuum pressure in a body hole formed in a body.

20. The aligning method of claim 18, wherein moving the mask plate comprises aligning the plurality of raw materials from a raw material with a small size that is 150 μm or less.
